(19) United States
(12) Patent Application Publication
(10) Pub. No.: US 2014/0103534 A1
(43) Pub. Date: Apr. 17, 2014

(54) ELECTROCHEMICAL DEPOSITION ON A WORKPIECE HAVING HIGH SHEET RESISTANCE

(71) Applicant: APPLIED Materials, Inc., Santa Clara, CA (US)

(72) Inventors: Ismail T. Emesh, Sunnyvale, CA (US); Roey Shaviv, Palo Alto, CA (US)

(73) Assignee: APPLIED MATERIALS, INC., Santa Clara, CA (US)

(21) Appl. No.: 13/915,566

(22) Filed: Jun. 11, 2013

Related U.S. Application Data
(63) Continuation-in-part of application No. 13/801,786, filed on Mar. 13, 2013.
(60) Provisional application No. 61/638,851, filed on Apr. 26, 2012.

(51) Int. Cl. H01L 21/768

(52) U.S. Cl. CPC H01L 21/76882
USPC 257/773; 438/653

(57) ABSTRACT

A method for at least partially filling a feature on a workpiece generally includes obtaining a workpiece including a feature, depositing a first conductive layer in the feature, wherein the sheet resistance of the first conductive layer is greater than 10 ohm/square, depositing a second conductive layer in the feature by electrochemical deposition, wherein the electrical contacts are at least partially immersed in the deposition chemistry.

### CROSS-REFERENCES TO RELATED APPLICATIONS

This application is a continuation-in-part of U.S. patent application Ser. No. 13/801,786, filed Mar. 13, 2013, which claims the benefit of U.S. Provisional Application No. 61/638,851, filed Apr. 26, 2012, the disclosures of which are hereby expressly incorporated by reference herein in their entirety.

### BACKGROUND

The present disclosure relates to methods for electrochemically depositing a conductive material, for example, a metal, such as copper (Cu), cobalt (Co), nickel (Ni) gold (Au), silver (Ag), manganese (Mn), tin (Sn), aluminum (Al), and alloys thereof, in features (such as trenches and vias, particularly in Damascene applications) of a microelectronic workpiece.

An integrated circuit is an interconnected ensemble of devices formed within a semiconductor material and within a dielectric material that overlies a surface of the semiconductor material. Devices which may be formed within the semiconductor include MOS transistors, bipolar transistors, diodes, and diffused resistors. Devices which may be formed within the dielectric include thin film resistors and capacitors. The devices are interconnected by conductor paths formed within the dielectric. Typically, two or more levels of conductor paths, with successive levels separated by a dielectric layer, are employed as interconnections. In current practice, copper and silicon oxide are commonly used for, respectively, the conductor and the dielectric.

The deposits in a copper interconnect typically include a dielectric layer, a barrier layer, a seed layer, copper fill, and a copper cap. Because copper tends to diffuse into the dielectric material, barrier layers are used to isolate the copper deposit from the dielectric material. However, for other metal interconnects besides copper, it should be appreciated that barrier layers may not be required. Barrier layers are typically made of refractory metals or refractory compounds, for example, titanium (Ti), tantalum (Ta), titanium nitride (TiN), tantalum nitride (TaN), etc. Other suitable barrier layer materials may include manganese (Mn) and manganese nitride (MnN). The barrier layer is typically formed using a deposition technique called physical vapor deposition (PVD), but may also be formed by using other deposition techniques, such as chemical vapor deposition (CVD) or atomic layer deposition (ALD).

A seed layer may be deposited on the barrier layer. However, it should also be appreciated that direct on barrier (DOB) deposition is also within the scope of the present disclosure, for example, barriers that are made from alloys or co-deposited metals upon which interconnect metals may be deposited without requiring a separate seed layer, such as titanium ruthenium (TiRu), tantalum ruthenium (TaRu), tungsten ruthenium (WRu), as well as other barrier layers that are known and/or used by those having skill in the art.

In one non-limiting example, the seed layer may be a copper seed layer. As another non-limiting example, the seed layer may be a copper alloy seed layer, such as copper manganese, copper cobalt, or copper nickel alloys. In the case of depositing copper in a feature, there are several exemplary options for the seed layer. First, the seed layer may be a PVD copper seed layer. See, e.g., FIG. 3 for an illustration of a process including PVD copper seed deposition. The seed layer may also be formed by using other deposition techniques, such as CVD or ALD.

Second, the seed layer may be a stack film, for example, a liner layer and a PVD seed layer. A liner layer is a material used in between a barrier and a PVD seed to mitigate discontinuous seed issues and improve adhesion of the PVD seed. Liners are typically noble metals such as ruthenium (Ru), platinum (Pt), palladium (Pd), and osmium (Os), but the list may also include cobalt (Co) and nickel (Ni). Currently, CVD Ru and CVD Co are common liners; however, liner layers may also be formed by using other deposition techniques, such as ALD or PVD.

Third, the seed layer may be a secondary seed layer. A secondary seed layer is similar to a liner layer in that it is typically formed from noble metals such as Ru, Pt, Pd, and Os, but the list may also include Co and Ni, and most commonly CVD Ru and CVD Co. (Like seed and liner layers, secondary seed layers may also be formed by using other deposition techniques, such as ALD or PVD.) The difference is that the secondary seed layer serves as the seed layer, whereas the liner layer is an intermediate layer between the barrier layer and the PVD seed. See, e.g., FIGS. 5 and 6 for illustrations of processes including secondary seed depositions, followed by, respectively, ECD seed deposition in FIG. 5, as described below, and flash deposition in FIG. 6. (A “flash” deposition is primarily on the field and at the bottom of the feature, without significant deposition on the sidewalls of the feature.)

After a seed layer has been deposited according to one of the examples described above, the feature may include a seed layer enhancement (SLE) layer, which is a thin layer of deposited metal, for example, copper having a thickness of about 2 nm. An SLE layer is also known as an electrochemically deposited seed (or ECD seed). See, e.g., FIG. 4 for an illustration of a process including PVD seed deposition and ECD seed deposition. See, e.g., FIG. 5 for an illustration of a process including secondary seed deposition and ECD seed deposition. As seen in FIGS. 4 and 5, ECD seed may be a conformally deposited layer.

An ECD copper seed is typically deposited using a basic chemistry that includes a very dilute copper ethylenediamine (EDA) complex. ECD copper seed may also be deposited using other copper complexes, such as citrate, tartrate, urea, etc., and may be deposited in a pH range of about 2 to about 11, about 3 to about 10, or in a pH range of about 4 to about 10.

After a seed layer has been deposited according to one of the examples described above (which may also include an optional ECD seed), conventional ECD fill and cap may be performed in the feature, for example, using an acid deposition chemistry. Conventional ECD copper acid chemistry may include, for example, copper sulfate, sulfuric acid, methane sulfonic acid, hydrochloric acid, and organic additives (such as accelerators, suppressors, and levelers). Electrochemical deposition of copper has been found to be the most cost effective manner by which to deposit a copper metallization layer. In addition to being economically viable, ECD deposition techniques provide a substantially bottom up (e.g., nonconformal) metal fill that is mechanically and electrically suitable for interconnect structures.

Conventional ECD fill, particularly in small features, may result in a lower quality interconnect. For example, conventional ECD copper fill may produce voids, particularly in features having a size of less than 30 nm. As one example of a type of void formed using conventional ECD deposition, the opening of the feature may pinch off. Other types of voids can also result from using the conventional ECD copper fill process in a small feature. Such voids and other intrinsic properties of a deposit formed using conventional ECD copper fill can increase the resistance of the interconnect, thereby slowing down the electrical performance of the device and deteriorating the reliability of the copper interconnect.

Therefore, there exists a need for an improved, substantially void-free metal fill process for a feature. Such substantially void-free metal fill may be useful in a small feature, for example, a feature having an opening size of less than 30 nm.

As feature size gets smaller and smaller, the thin deposit layers that make up the interconnect tend to have very high sheet resistance, which can create difficulties in electrochemical deposition. Therefore, there exists a need for systems and methods for electrochemical deposition on a conductive layer having a sheet resistance value, for example, greater than 10 ohm/sq.

Embodiments of the present disclosure are directed at solving these and other problems.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In accordance with one embodiment of the present disclosure, a method for at least partially filling a feature on a workpiece is provided. The method generally includes obtaining a workpiece including a feature, depositing a first conductive layer in the feature, wherein the sheet resistance of the first conductive layer is greater than 10 ohm/square, depositing a second conductive layer in the feature by electrochemical deposition, wherein the electrical contacts are at least partially immersed in the deposition chemistry.

In accordance with one embodiment of the present disclosure, a method for at least partially filling a feature on a workpiece is provided. The method generally includes obtaining a workpiece including a feature, depositing a seed layer in the feature, wherein the sheet resistance of the first conductive layer is greater than 10 ohm/square, and depositing a conductive layer in the feature on the seed layer by electrochemical deposition, wherein the electrical contacts are at least partially immersed in the deposition chemistry.

In accordance with one embodiment of the present disclosure, a workpiece is provided. The workpiece generally includes a feature, a first conductive layer in the feature, wherein the sheet resistance of the first conductive layer is greater than 10 ohm/square, and a second conductive layer in the feature, wherein the second conductive layer covers the entire surface of the first conductive layer.

### DESCRIPTION OF THE DRAWINGS

The foregoing aspects and many of the attendant advantages of this disclosure will become more readily appreciated by reference to the following detailed description, when taken in conjunction with the accompanying drawings, wherein:

FIG. 1 is a schematic flow diagram depicting the process steps and an exemplary feature development of an exemplary embodiment of the present disclosure;

FIG. 2 is a comparison chart of exemplary process steps that may be used in conjunction with prior art processes and processes according to embodiments of the present disclosure;

FIG. 3 is a schematic process diagram depicting the process steps and an exemplary feature development using a prior art main Damascene process, including barrier deposition, seed deposition, and conventional ECD fill and cap deposition;

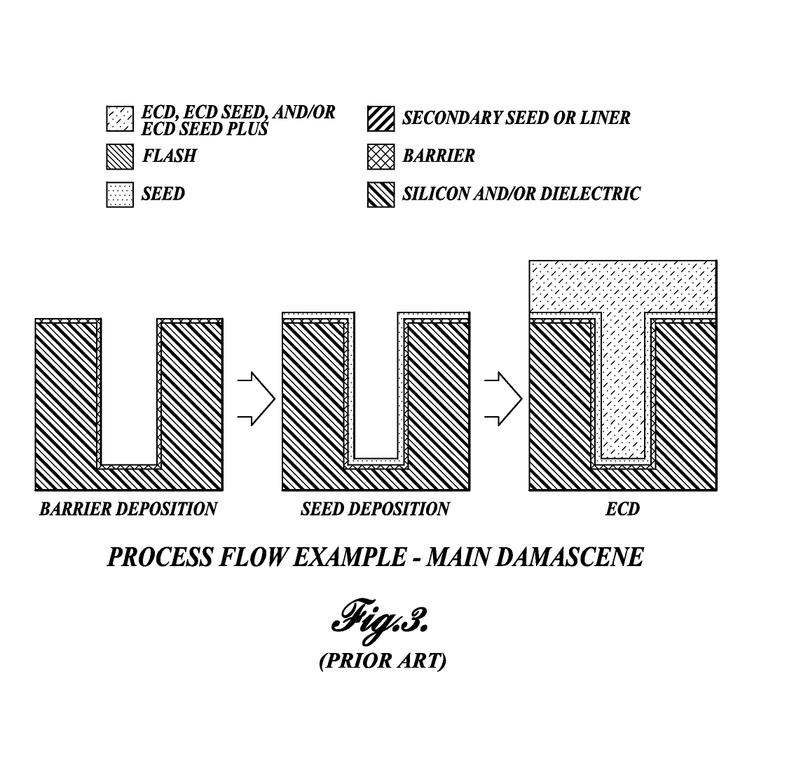

FIG. 4 is a schematic process diagram depicting the process steps and an exemplary feature development using a prior art SLE (also know as ECD seed) process, including barrier deposition, seed deposition, ECD seed deposition, and conventional ECD fill and cap deposition;

FIG. 5 is a schematic process diagram depicting the process steps and an exemplary feature development using a prior art ECD seed process, including barrier deposition, secondary seed deposition, ECD seed deposition, and conventional ECD fill and cap deposition;

FIG. 6 is a schematic process diagram depicting the process steps and an exemplary feature development using a prior art deposition on secondary seed process with a flash layer, including barrier deposition, secondary seed deposition, flash deposition, and conventional ECD fill and cap deposition;

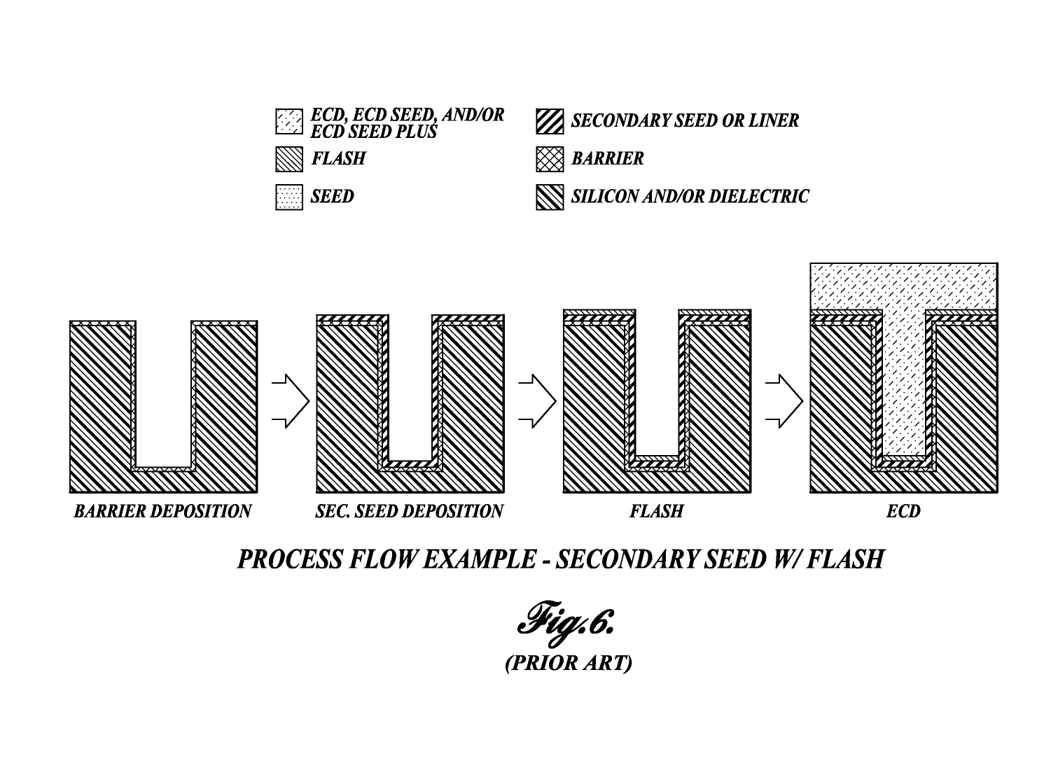

FIG. 7 is a schematic process diagram depicting the process steps and an exemplary feature development of a number of exemplary embodiments of the present disclosure;

FIG. 8 is a graphical depiction of exemplary process steps for deposition in Damascene features having feature diameters of about 30 nm according to the embodiments of the present disclosure for various exemplary wafers;

FIG. 9 is a graphical depiction of 120 micron long line resistor resistance results obtained from exemplary wafers described in FIG. 8;

FIG. 10 is a graphical depiction of 1 meter long line resistor resistance results obtained from exemplary wafers described in FIG. 8;

FIG. 11 is a graphical depiction of 1 meter long resistor resistive-capacitive delay results obtained from exemplary wafers described in FIG. 8;

FIG. 12 includes a transmission electron microscopy (TEM) image of substantially void-free gap fill for a Damascene feature having a feature diameter of about 30 nm in accordance with embodiments of the present disclosure; and

FIGS. 13A and 13B are schematics depicting exemplary workpieces in accordance with embodiments of the present disclosure.

### DETAILED DESCRIPTION

Embodiments of the present disclosure are directed to workpieces, such as semiconductor wafers, devices or processing assemblies for processing workpieces, and methods of processing the same. The term workpiece, wafer, or semiconductor wafer means any flat media or article, including semiconductor wafers and other substrates or wafers, glass, mask, and optical or memory media, MEMS substrates, or any other workpiece having micro-electric, micro-mechanical, or microelectro-mechanical devices.

Processes described herein are to be used for metal or metal alloy deposition in features of workpieces, which include trenches and vias. In one embodiment of the present disclosure, the process may be used in small features, for example, features having a feature diameter or critical dimension of less than 30 nm. However, it should be appreciated that the processes described herein are applicable to any feature size. The dimension sizes discussed in the present application are post-etch feature dimensions at the top opening of the feature. The processes described herein may be applied to various forms of copper, cobalt, nickel, gold, silver, manganese, tin, aluminum, and alloy deposition, for example, in Damascene applications. In embodiments of the present disclosure, Damascene features may be selected from the group consisting of features having a size of less than 30 nm, about 5 to less than 30 nm, about 10 to less than 30 nm, about 15 to about 20 nm, about 20 to less than 30 nm, less than 20 nm, less than 10 nm, and about 5 to about 10 nm.

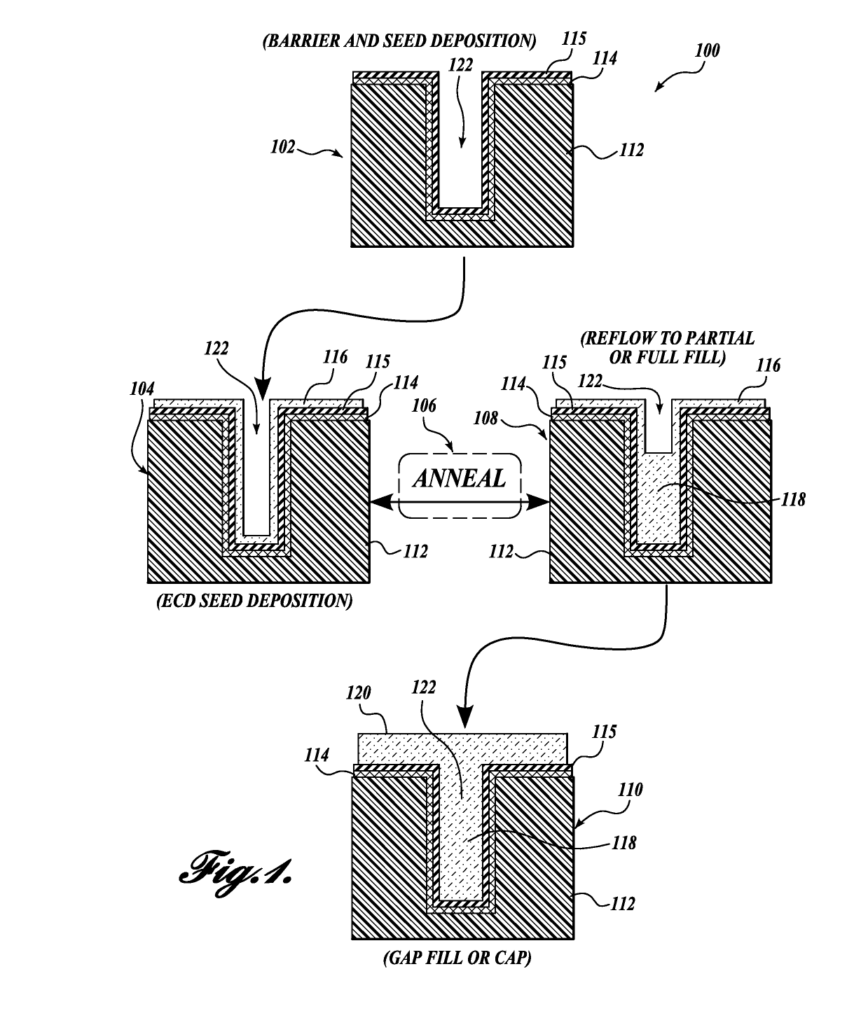

It should be appreciated that the descriptive terms “micro-feature workpiece” and “workpiece” as used herein include all structures and layers that have been previously deposited and formed at a given point in the processing, and is not limited to just those structures and layers as depicted in FIG. 1.

It should be appreciated that processes described herein may also be modified for metal or metal alloy deposition in high aspect ratio features, for example, vias in through silicon via (TSV) features, as described in U.S. patent application Ser. No. 13/801,860 (Docket No. 017214USA02; SEMT-1-39699), filed on Mar. 13, 2013, the disclosure of which is incorporated by reference herein in its entirety.

Although generally described as metal deposition in the present application, it should be appreciated that the term “metal” also contemplates metal alloys. Such metals and metal alloys may be used to form seed layers or to fully or partially fill the feature. Exemplary copper alloys may include, but are not limited to, copper manganese and copper aluminum. As a non-limiting example, the alloy composition ratio may be in the range of about 0.5% to about 6% secondary alloy metal, as compared to the primary alloy metal (e.g., Cu, Co, Ni, Ag, Au, etc.).

As described above, the conventional fabrication of metal interconnects may include a suitable deposition of a barrier layer on the dielectric material to prevent the diffusion of metal into the dielectric material. Suitable barrier layers, which may include, for example, Ta, Ti, TiN, TaN, Mn, or MnN. Suitable barrier deposition methods may include PVD, ALD and CVD; however, PVD is the most common process for barrier layer deposition. Barrier layers are typically used to isolate copper or copper alloys from dielectric material; however, it should be appreciated that in the case of other metal interconnects, diffusion may not be a problem and a barrier layer may not be required.

The barrier layer deposition may be followed by an optional seed layer deposition. In the case of depositing metal in a feature, there are several options for the seed layer. As described above, the seed layer may be (1) a seed layer (as a non-limiting example, a PVD copper seed layer). The seed layer may be a metal layer, such as copper, cobalt, nickel, gold, silver, manganese, tin, aluminum, ruthenium, and alloys thereof. The seed layer may also be (2) a stack film of a liner layer and a seed layer (as a non-limiting example, a CVD Ru liner layer and a PVD copper seed layer), or (3) a secondary seed layer (as a non-limiting example, a CVD or ALD Ru secondary seed layer). It should be appreciated, however, that other methods of depositing these exemplary seed layers are contemplated by the present disclosure.

As discussed above, a liner layer is a material used in between a barrier layer and a seed layer to mitigate discontinuous seed issues and improve adhesion of the seed layer. Liners are typically noble metals such as Ru, Pt, Pd, and Os, but the list may also include Co and Ni. Currently, CVD Ru and CVD Co are common liners; however, liner layers may also be formed by using other deposition techniques, such as PVD or ALD. The thickness of the liner layer may be in the range of around 5 Å to 50 Å for Damascene applications.

Also discussed above, a secondary seed layer is similar to a liner layer in that it is typically formed from noble metals such as Ru, Pt, Pd, and Os, but the list may also include Co and Ni, and most commonly CVD Ru and CVD Co. The difference is that the secondary seed layer serves as the seed layer, whereas the liner layer is an intermediate layer between the barrier layer and the seed layer. Secondary seed layers may also be formed by using other deposition techniques, such as PVD or ALD.

The liner or secondary seed deposit may be thermally treated or annealed at a temperature between about 100° C. to about 500° C. in a pure H2 gas environment (either at atmospheric or reduced pressure) or a forming gas environment (e.g., 3-5% hydrogen in nitrogen or 3-5% hydrogen in helium) to remove any surface oxides, densify the secondary seed or liner layer, and improve the surface properties of the deposit. The liner or secondary seed deposit may additionally be passivated by the soaking in gaseous nitrogen (N2 gas) or other passivating environments to prevent surface oxidation. Passivation of the liner or secondary seed is described in U.S. Pat. No. 8,357,599, issued Jan. 22, 2013, the disclosure of which is hereby expressly incorporated by reference in its entirety.

After a seed layer has been deposited (such as one of the non-limiting examples of PVD copper seed, PVD copper seed including CVD Ru liner, or CVD Ru secondary seed, or another deposition metal or metal alloy, layer combination, or deposition technique), the feature may include a conformal metal layer after the seed layer. It should also be appreciated, however, that a conformal metal layer may be deposited directly on the barrier layer, i.e., without a seed layer.

In one embodiment of the present disclosure, the conformal layer is deposited using an ECD seed process, and then may be modified using a process that is referred to as ECD seed “plus” deposition (or ECD seed “plus”), which includes a thermal treatment step. In other embodiments of the present disclosure, the conformal layer may be deposited using CVD, ALD, or other deposition techniques, such as electroless deposition, and then may be subject to a thermal treatment step. In accordance with embodiments of the present disclosure, the conformal layer is “flowable” or capable of mobility when subjected to thermal treatment or annealing.

In this embodiment, ECD seed “plus” generally refers to ECD metal seed deposition plus a thermal treatment step, such as an annealing step. In one embodiment of the present disclosure, the thermal treatment step may result in reflow of some or all of the seed deposition. An increase in temperature in the ECD seed layer aids in the mobility of the atoms in the layer and enhances their ability to fill the structure.

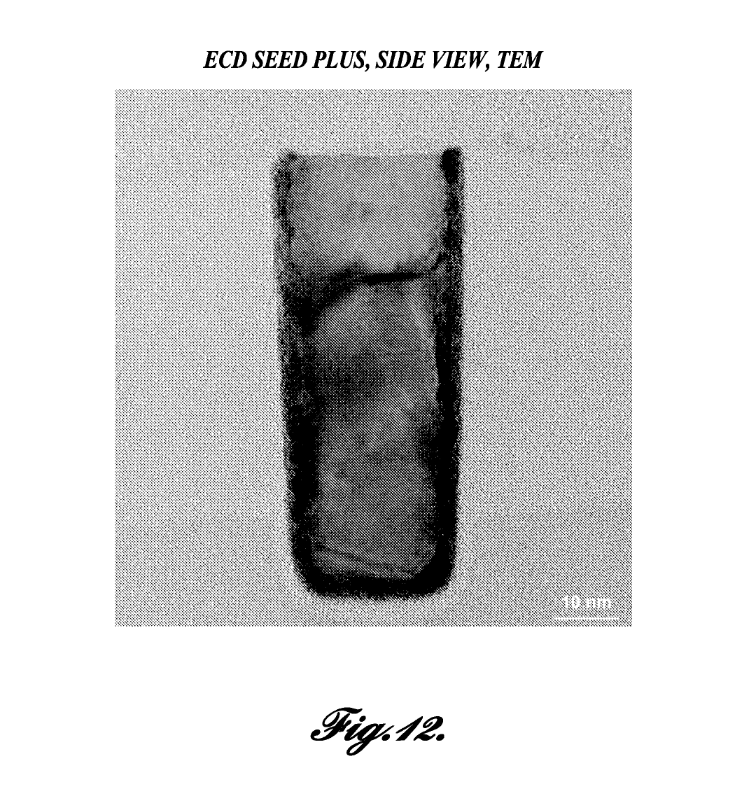

In contrast to conventional ECD metal fill (using acid chemistry), ECD seed “plus” deposition is similar to ECD seed deposition (using basic chemistry), but adds a thermal treatment step. Moreover, instead of just depositing a seed layer, ECD seed “plus” can be performed so as to partially fill or fully fill the features. With the ECD seed “plus” process, substantially void-free fill of small features can be achieved, as described in greater detail below (see image of substantially void-free fill in a small feature in FIG. 12).

The chemistry used in the ECD chamber for ECD seed “plus” deposition may include a basic chemistry, for example, Cu(ethylenediamine)2 at a pH in the range of about 8 to about 11, in one embodiment of the present disclosure about 8 to about 10, and in one embodiment of the present disclosure about 9.3. It should be appreciated, however, that acidic chemistries using proper organic additives may also be used to achieve conformal ECD seed deposition.

After ECD seed deposition, the workpiece may then be subjected to the spin, rinse, and dry (SRD) process or other cleaning processes. The ECD seed is then heated at a temperature warm enough to get the seed to reflow, but not too hot such that the workpiece or elements on the workpiece are damaged or degraded. For example, the temperature may be in the range of about 100° C. to about 500° C. for seed reflow in the features. Appropriate thermal treatment or annealing temperatures are in the range of about 100° C. to about 500° C., and may be accomplished with equipment capable of maintaining sustained temperatures in the range of about 200° C. to about 400° C., and at least within the temperature range of about 250° C. to about 350° C.

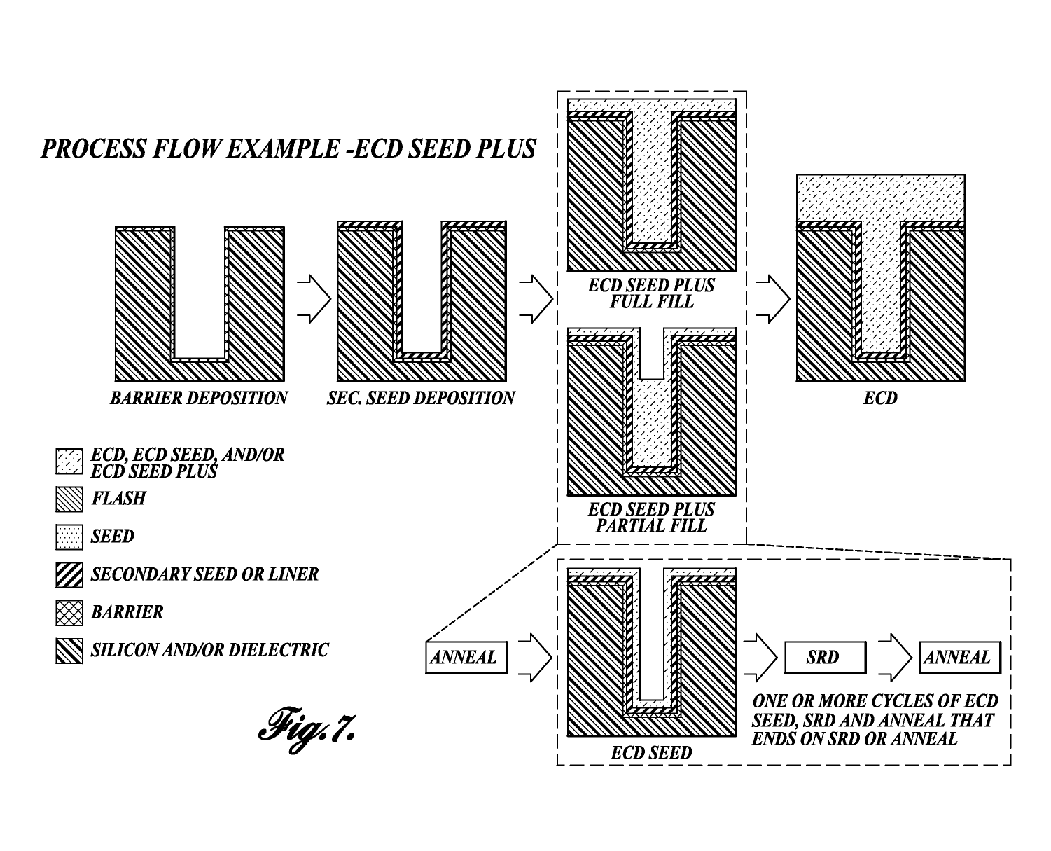

The thermal treatment or annealing process may be performed using a forming or inert gas, pure hydrogen, a mixture of hydrogen and helium, or a reducing gas such as ammonia (NH3). During reflow, the shape of the deposition changes, such that the metal deposit may pool in the bottom of the feature, as shown in FIG. 7. In addition to reflow during the thermal treatment process, the metal deposit may also grow larger grains and reduce film resistivity. An inert gas may be used to cool the workpiece after heating.

After the ECD seed “plus” deposition and thermal treatment process has been completed to either partially or completely fill the feature, a conventional acid chemistry may be used to complete the deposition process for gap fill and cap deposition. The acid chemistry metal deposition step is generally used to fill large structures and to maintain proper film thickness needed for the subsequent polishing step because it is typically a faster process than ECD seed, saving time and reducing processing costs.

As seen in FIGS. 1 and 7, the ECD seed deposition and reflow steps may be repeated to ensure complete filling of the feature with ECD seed. In that regard, processes described herein may include one or more ECD seed deposition, cleaning (such as SRD), and thermal treatment cycles.

Referring to FIG. 1, a reflow process 100 and exemplary features created by the reflow process are depicted. The workpiece 112 may be in an exemplary embodiment a dielectric material on a crystalline silicon workpiece that contains at least one feature 122. In exemplary step 102, the feature 122 is lined with a barrier layer 114 and a seed layer 115. In exemplary step 104, the feature 122 of the workpiece 112 has received a layer of ECD seed material 116 on the seed layer 115. In exemplary anneal step 106, the workpiece is annealed at an appropriate temperature to induce the exemplary reflow step 108 to encourage partial fill or full fill. During the anneal step, ECD seed material 116 flows into the feature 122 to form a fill 118, while having minimal, if any, detrimental effect on the workpiece 112 or the features included therein. In an exemplary embodiment, ECD seed deposition step 104, anneal step 106, and reflow step 108 may be repeated to attain the desired characteristics of fill 118. The number of repeating steps may depend on the structure. Once fill 118 reaches desired dimensions, exemplary cap step 110 may be used to complete the process in which additional material 120 is deposited above the feature in preparation for additional workpiece 112 processing.

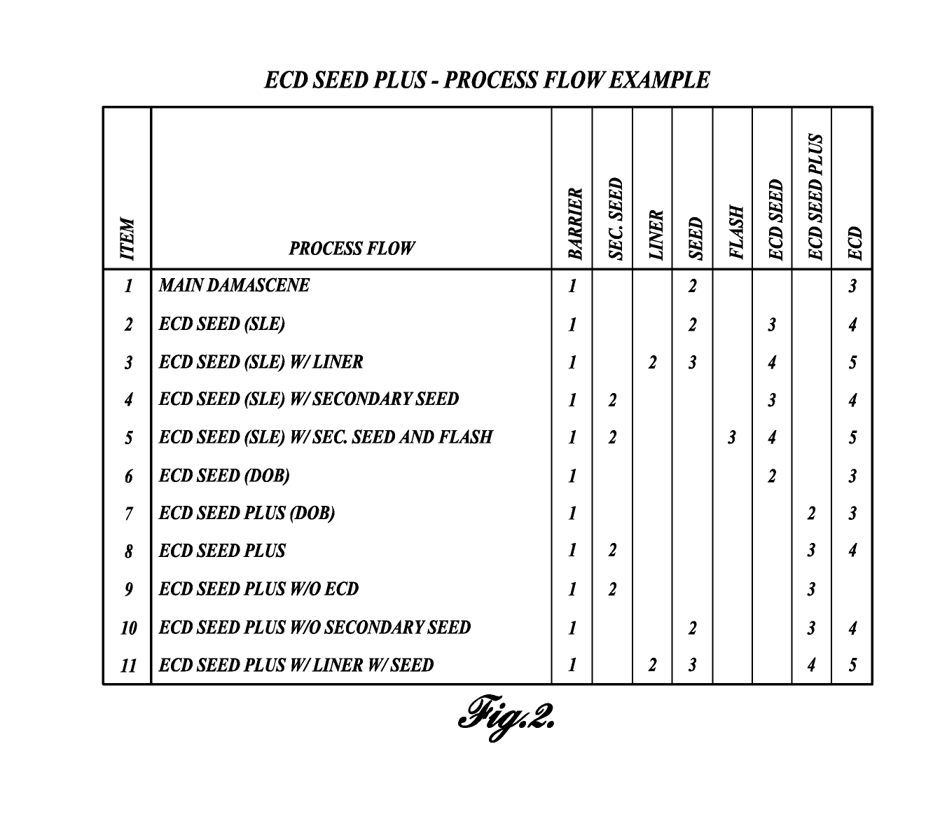

Referring now to FIG. 2, process flow examples are provided wherein embodiments of the present disclosure may be used in conjunction with, and integrated into other workpiece surface deposition processes. The previously developed processes will first be described. First, the TSV process includes deposition of a barrier layer, a seed layer, and a conventional ECD fill. Second, the ECD Seed (also known as SLE) process includes deposition of a barrier layer, a seed layer, an ECD seed layer, and a conventional ECD fill. Third, the ECD Seed (SLE) With Liner process includes deposition of a barrier layer, a liner layer, a seed layer, an ECD seed layer, and a conventional ECD fill. Fourth, the ECD Seed (SLE) With Secondary Seed process includes deposition of a barrier layer, a secondary seed layer, an ECD seed layer, and a conventional ECD fill. Fifth, the ECD Seed (SLE) With Secondary Seed and Flash process includes deposition of a barrier layer, a secondary seed layer, a flash layer, an ECD seed layer, and a conventional ECD fill. Sixth, the ECD Seed (DOB) process includes deposition of a barrier layer, an ECD seed layer, and a conventional ECD fill. This is a DOB process because there is no deposition of a secondary seed, liner, or seed layer, rather, the ECD seed layer is deposited directly on a platable barrier layer.

Still referring to FIG. 2, the processes in accordance with embodiments of the present disclosure will now be described. Seventh, the ECD Seed Plus (DOB) process includes deposition of a barrier layer, an ECD seed “plus” deposit, and a conventional ECD fill and/or cap. Like the sixth example above, this is also a DOB process because there is no deposition of a secondary seed, liner, or seed layer; rather, the ECD seed layer is deposited directly on a platable barrier layer. Eighth, the ECD Seed Plus process includes deposition of a barrier layer, a secondary seed layer, an ECD seed “plus” deposit, and a conventional ECD fill and/or cap. Ninth, the ECD Seed Plus Without ECD process includes deposition of a barrier layer, a secondary seed layer, and an ECD seed “plus” deposit. Tenth, the ECD Seed Plus Without Secondary Seed process includes deposition of a barrier layer, a seed layer, an ECD seed “plus” deposit, and a conventional ECD fill and/or cap. Eleventh, the ECD Seed Plus With Liner and Seed process includes deposition of a barrier layer, a liner layer, a seed layer, an ECD seed “plus” deposit, and a conventional ECD fill and/or cap.

Referring to FIG. 7, another exemplary process in accordance with embodiments of the present disclosure is provided. In a first step, a workpiece having a barrier layer and a secondary seed layer is thermally treated or annealed prior to the ECD seed step to remove any surface oxides, densify the deposit, and improve the surface properties of the deposit. The seed layer shown in FIG. 7 is a secondary seed layer, but it should be appreciated that it may also be a seed layer or a stack film of a liner layer and a seed layer. Suitable thermal treatment or annealing conditions may include temperatures between about 200° C. to about 400° C. for about one (1) to about ten (10) minutes, possibly in forming gas or pure hydrogen. As mentioned above, the workpiece could alternatively be thermally treated in inert gas such as N2, argon (Ar) or helium (He). A reducing gas such as ammonia (NH3) may also be used.

In a second step, the workpiece is transferred to a deposition chamber for conformal deposition of an ECD seed layer. The thickness of the deposited film varies depending on the feature dimension and desired properties of the metal deposit.

In a third step, the workpiece is spun, rinsed with deionized (DI) water, and dried (SRD) to clean the workpiece.

In a fourth step, the workpiece is thermally treated or annealed at temperature in the range of 200° C. to 400° C. for reflow the metal into the feature.

In a fifth step, the workpiece may undergo sequential retreating of steps 2, 3, and 4, until a desired fill profile of the feature on the workpiece is obtained.

In a sixth step, the workpiece is subjected to conventional ECD acid chemistry deposition to achieve a desired thickness. The workpiece is then ready for subsequent processing, which may include additional thermal treatment, chemical mechanical polishing, and other processes.

Alternate embodiments of the process may include variations of the steps already described herein, and those steps, combinations and permutations may additionally be integrated into the following additional steps. It is envisioned in this disclosure that conformal “seed” deposition can be performed in basic solution or in acid solution, for example, in a pH range of about 4 to about 10, about 3 to about 10, or about 2 to about 11, with or without organic additives such as suppressors, accelerators, and/or levelers. Reflow may be performed using multiple deposition, cleaning (e.g., SRD), and thermal treatment or annealing steps or can be done in single step followed by thermal treatment or annealing at the appropriate temperature.

ECD seed “plus” deposition is important for the development of small features because the thermal treatment or annealing and reflowing steps provide for substantially void-free seed deposition. As described in greater detail below, void formation in the features increases the resistance (slows down the electrical performance of the device) and deteriorates the reliability of the interconnect.

Other advantages are realized by using the processes described herein. In that regard, a single tool for example a Raider® electrochemical deposition, cleaning (e.g., SRD), and thermal treatment or anneal tool, manufactured by Applied Materials, Inc., can be used for the ECD seed deposition step (or steps if repeated), the cleaning step (or steps if repeated), the thermal treatment step (or steps if repeated), and for the final ECD step. Moreover, the results show substantially void-free gap fill for small features using the processes described herein, resulting in lower resistance and resistive-capacitive (RC) delay values. In addition, the processes described herein provide the ability to fill a small feature on the order of less than about 30 nm, whereas fill may not be achieved using conventional processes. ECD seed “plus” deposition is also advantageous in features larger than 30 nm.

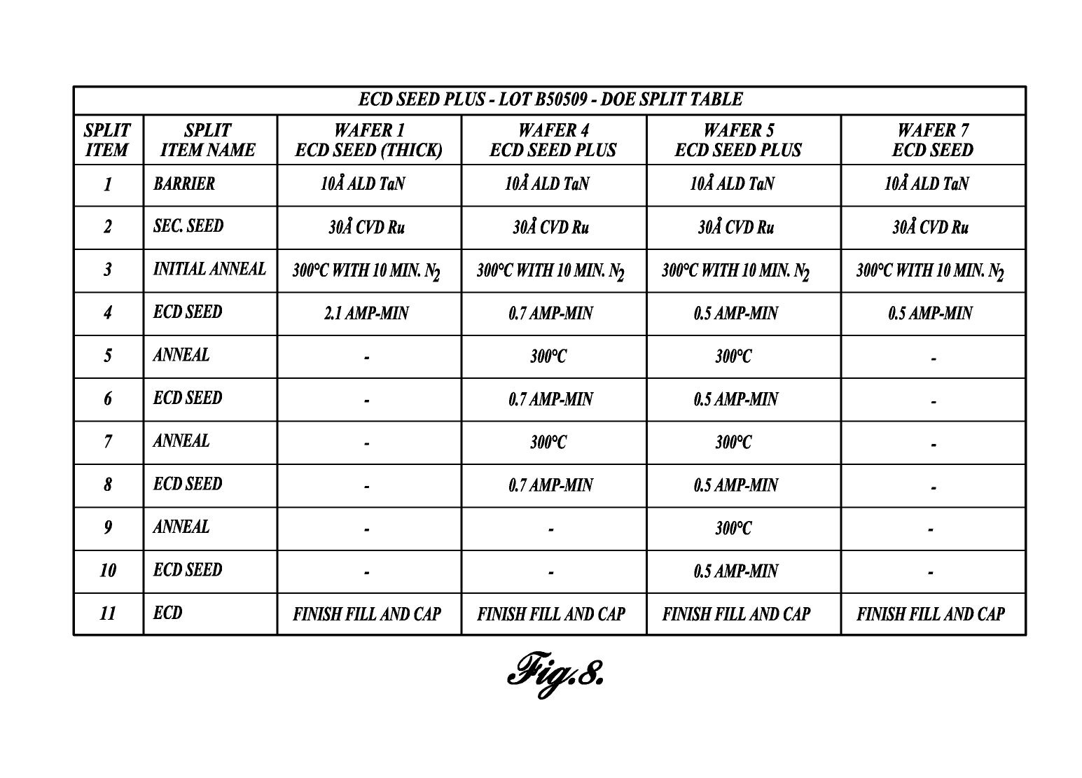

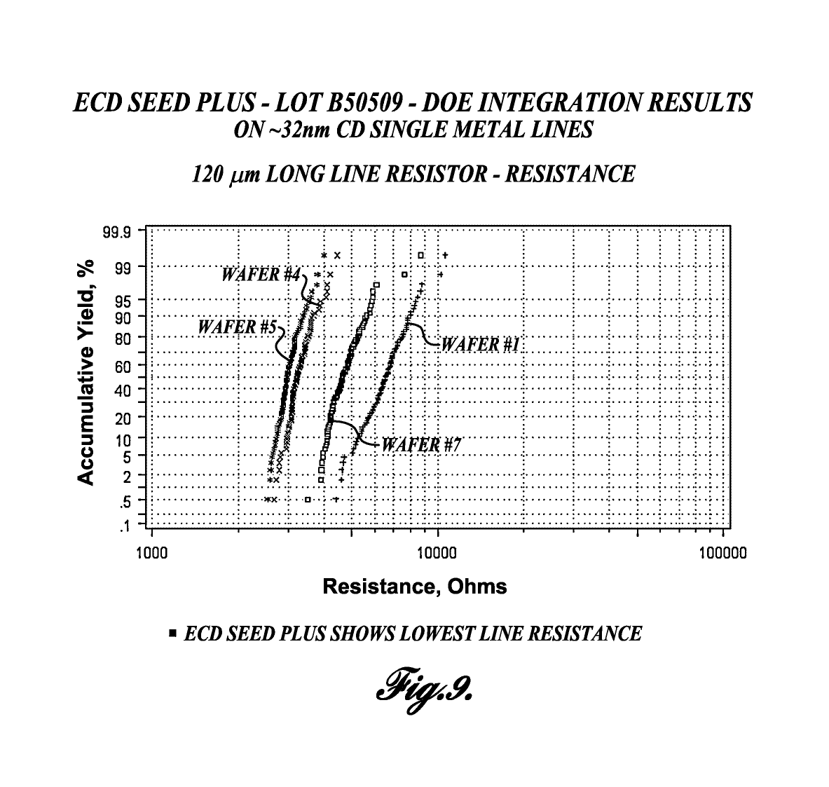

As mentioned above, one or more layers of ECD seed may be applied and then exposed to an elevated temperature to fill deeper or high aspect ratio features. Referring to FIG. 8, two exemplary ECD seed plus processes (including annealing steps) are provided [Wafer 4 and Wafer 5], as compared to two conventional ECD seed process (without annealing steps) [Wafer 1 and Wafer 7] for deposition in Damascene features having feature diameters of about 30 nm. Referring to FIGS. 9 through 11, the results show that incremental deposition of the ECD seed in Damascene features, with some or all deposition steps followed by annealing step, results in reduced resistance and resistive-capacitive (RC) delay values as compared to a single step of ECD seed (i.e., without an anneal step).

All of Wafers 1, 4, 5, and 7 include the following initial process conditions: A barrier layer of 10 Å ALD TaN was deposited, followed by a seed layer (secondary seed) of 30 Å CVD Ru, and then the workpieces were subjected to an anneal at 300° C. with 10 minutes of nitrogen passivation.

Wafers 1 and 7 were then plated with a single step of ECD copper seed at, respectively, 2.1 amp-min and 0.5 amp-min, then were finished with fill and cap using a conventional acid ECD copper deposition process. The resultant workpieces produced a thick ECD copper seed (Wafer 1) and a thin ECD copper seed (Wafer 7).

Wafers 4 and 5 were subjected to ECD seed “plus” conditions. Wafer 4 included three ECD copper seed steps, each at 0.7 amp-min with a 300° C. anneal after each of the first two steps and no anneal after the third step, then finished with fill and cap using a conventional acid ECD copper deposition process. A microscopy image associated with Wafer 4, which has a feature size of approximately 30 nm, is provided in FIG. 12. Although there is no anneal after the third step, it should be appreciated that a final anneal step is also within the scope of the present disclosure.

Wafer 5 included four ECD copper seed steps, each at 0.5 amp-min with a 300° C. anneal after the first three steps and no anneal after the fourth step, then finished with fill and cap using a conventional acid ECD copper deposition process. Like Wafer 4, it should be appreciated that a final anneal step is also within the scope of the present disclosure.

Referring now to FIGS. 9 through 11, the comparative resistance and RC delay data for Wafers 1, 4, 5, and 7 is provided. As can be seen in FIGS. 9 through 11, the workpieces formed using ECD seed “plus” (Wafers 4 and 5) in accordance with methods described herein, have significantly reduced resistance and resistive/capacitive (RC) delay, as compared to workpieces formed using previously developed techniques (Wafers 1 and 7).

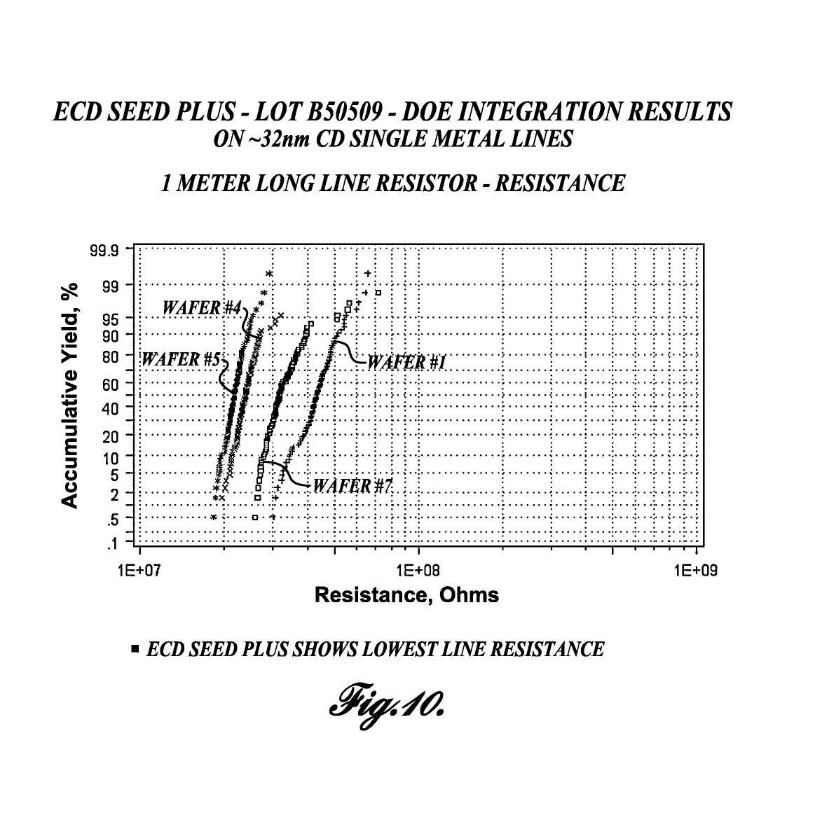

Referring to FIGS. 9 and 10, workpieces formed in accordance with embodiments of the present disclosure achieve resistance value reduction in the range of zero to about 40%, greater than zero to about 30%, greater than zero to about 20%, about 10% to about 20%, and about 10% to about 15%, as compared to workpieces formed using ECD seed, but without the ECD seed plus anneal cycle.

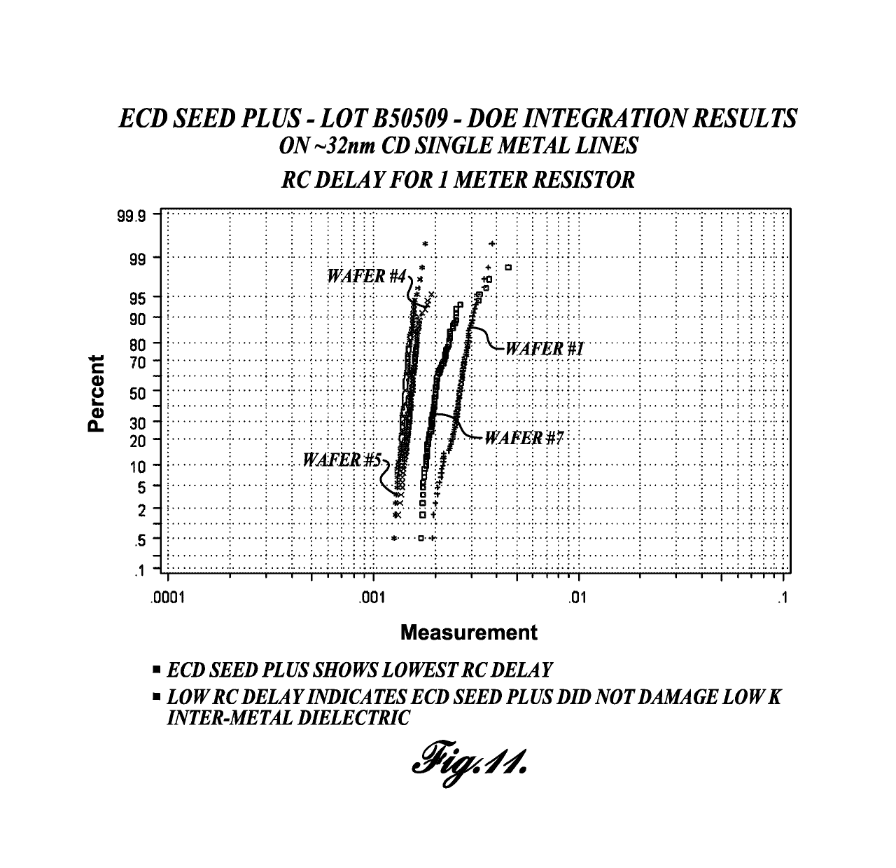

Referring to FIG. 11, workpieces formed in accordance with embodiments of the present disclosure achieve RC delay value reduction, as compared to workpieces formed using ECD seed, but without the ECD seed plus anneal cycle. Lower RC delay may result in lower or no damage to the low K inter-metal dielectric in the feature.

In accordance with other embodiments of the present disclosure, systems and methods for electrochemical deposition on a workpiece having high sheet resistance are provided. Returning to FIG. 1, as feature size gets smaller and smaller, for example, less than 30 nm, the thin deposit layers that make up the interconnect tend to have very high sheet resistance. High sheet resistance can create difficulties in electrochemical deposition (ECD) of subsequent metal layers, particularly when using “dry” electrical contacts. Embodiments of the present disclosure may apply to ECD deposition of ECD seed, ECD seed plus (including an annealing step, as described above), ECD fill and cap, or any other ECD deposition process on a workpiece.

Before performing an ECD metal deposition on a workpiece, a thin seed layer of metal is formed on the surface of a microelectronic workpiece, for example, using one of PVD, CVD, ALD, or electroless deposition processes. As described above, the seed layer may be a (1) a seed layer (as a non-limiting example, a PVD copper seed layer). The seed layer may be a metal layer, such as copper, cobalt, nickel, gold, silver, manganese, tin, aluminum, ruthenium, and alloys thereof. The seed layer may also be a co-plated metal layer, such as CoCu or MnCu mixtures, solid solutions or alloys. The seed layer may also be (2) a stack film of a liner layer and a seed layer (as a non-limiting example, a CVD Ru liner layer and a PVD copper seed layer), or (3) a secondary seed layer (as a non-limiting example, a CVD or ALD Co secondary seed layer). It should be appreciated, however, that other methods of depositing these exemplary seed layers are contemplated by the present disclosure.

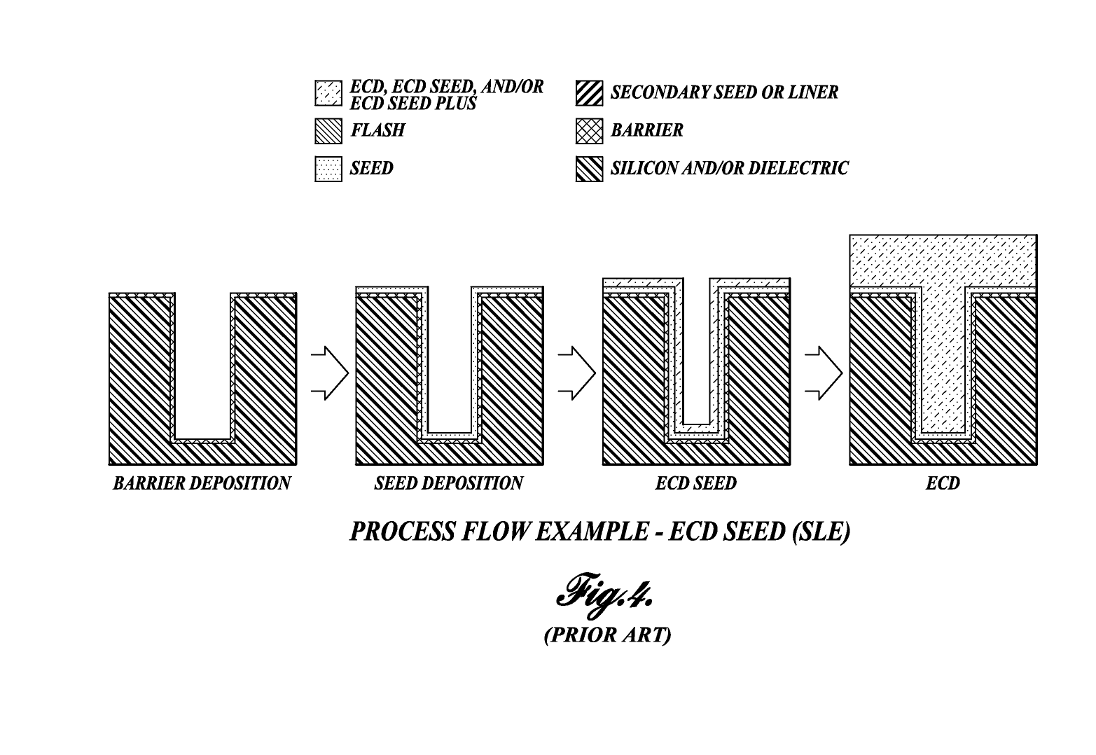

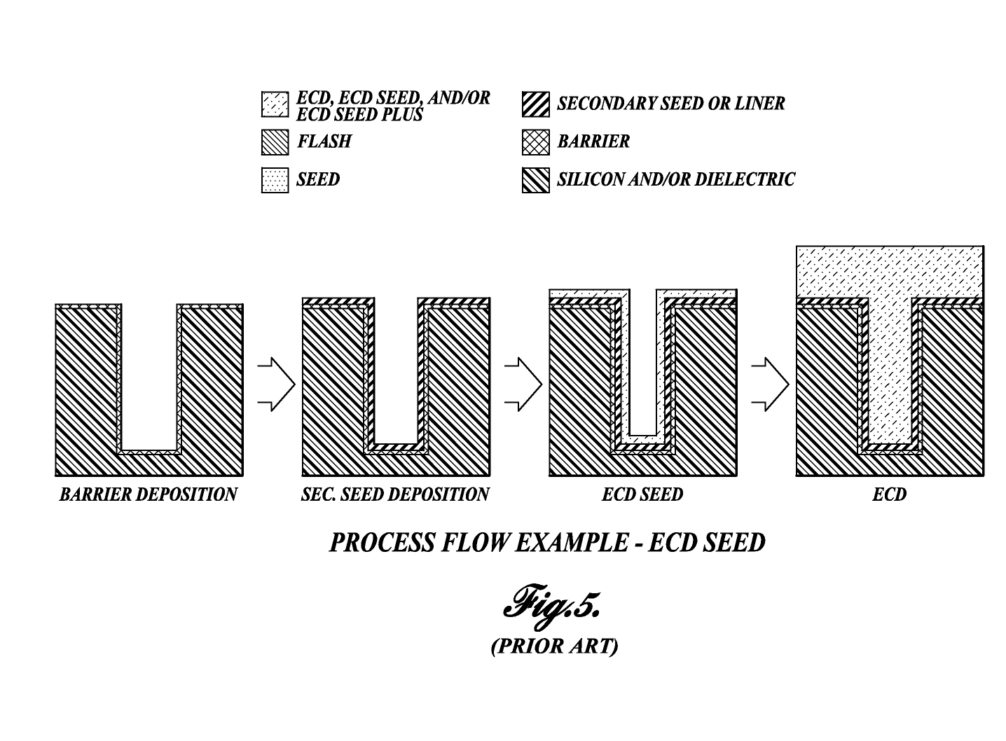

After a seed layer has been deposited according to one of the examples described above, the feature may include an SLE layer (or ECD seed). See, e.g., FIG. 4 for an illustration of a process including PVD seed deposition and ECD seed deposition. See, e.g., FIG. 5 for an illustration of a process including secondary seed deposition and ECD seed deposition. As seen in FIGS. 4 and 5, ECD seed may be a conformally deposited layer.

As discussed above, an ECD copper seed is typically deposited using a basic chemistry that includes a very dilute copper ethylenediamine (EDA) complex. ECD copper seed may also be deposited using other copper complexes, such as citrate, tartrate, urea, etc., and may be deposited in a pH range of about 2 to about 11, about 3 to about 10, or in a pH range of about 4 to about 10.

After a seed layer has been deposited according to one of the examples described above, the seed layer can be used as a cathode to deposit a metal layer onto the workpiece using an ECD deposition process, with the electrode functioning as an anode for metal deposition. The ECD metal deposit may be an ECD seed, ECD fill, or ECD cap deposit. While ECD seed is typically deposited using a basic chemistry, conventional ECD fill and cap may be performed in the feature, for example, using an acid deposition chemistry. Conventional ECD copper acid chemistry may include, for example, copper sulfate, sulfuric acid, methane sulfonic acid, hydrochloric acid, and organic additives (such as accelerators, suppressors, and levelers).

ECD tools for use in manufacturing microelectronic devices often have a number of single-wafer electroplating chambers. A typical chamber includes a container for holding an ECD chemistry, an anode in the container to contact the chemistry, and a support mechanism having a contact assembly with electrical contacts that engage the seed layer. The electrical contacts are coupled to a power supply to apply a voltage to the seed layer. In operation, the surface of the workpiece is immersed in the chemistry such that the anode and the seed layer establish an electrical field that causes metal ions in a diffusion layer at the front surface of the workpiece to plate onto the seed layer.

The structure of the contact assembly can influence the uniformity of the plated metal layer because the plating rate across the surface of the microelectronic workpiece is influenced by the distribution of the current (the “current density”) across the seed layer. One factor that affects the current density is the distribution of the electrical contacts around the perimeter of the workpiece. In general, a large number of discrete electrical contacts can be used to contact the seed layer proximate to the perimeter of the workpiece to provide a uniform distribution of current around the perimeter of the workpiece.

One type of contact assembly is a “dry-contact” assembly having a plurality of electrical contacts that are sealed from the ECD chemistry. For example, U.S. Pat. No. 5,227,041, issued to Brogden et al., describes a dry contact ECD structure having a base member for immersion into an ECD chemistry, a seal ring positioned adjacent to an aperture in the base member, a plurality of contacts arranged in a circle around the seal ring, and a lid that attaches to the base member. In operation, a workpiece is placed in the base member so that the front face of the workpiece engages the contacts and the seal ring. When the front face of the workpiece is immersed in the ECD chemistry, the seal ring prevents the ECD chemistry from engaging the contacts inside the base member.

Another type of contact assembly is a “wet-contact” assembly wherein the electrical contacts are permitted to contact the ECD chemistry. For example, U.S. Pat. No. 7,645,366, issued to Hanson et al., describes a wet-contact assembly that is immersed in the ECD chemistry.

When the sheet resistance of the seed layer is high, it is difficult to electrochemically deposit metal on the seed layer. In that regard, the sheet resistance of a very thin metal layer is inversely proportional to the thickness to the power of about 2 or more. For example, the sheet resistance of a copper film with thickness between 50 and 300 angstroms varies between 1.2 and 45 Ohm/Square and is inversely proportional to the thickness of the film to the power of about 2.2. In one non-limiting example, the sheet resistance of a 10 angstrom ruthenium seed layer can be greater than 600 ohms/sq. By comparison, the sheet resistance of a 50 angstrom ruthenium seed layer is less than 100 ohms/sq.

Moreover, the sheet resistance of very thin films can also vary according to the deposition method, the post-deposition treatment, and the time between process steps. In that regard, metals deposited by CVD or ALD methods tend to have higher sheet resistance than metals deposited by PVD or electroplating means. This difference may be the result of one or more factors, such as higher impurity levels, different grain structures, and a reaction with atmospheric oxygen or moisture. This phenomenon is manifest for Co, Ru, TiN, Mn and many other metals. For example, CVD Co films were measured at higher than 1000 Ohm/square, compared with a lower value for a PVD Co film of the same thickness.

Electrochemical deposition requires current conduction through the plated surface. The current supplies the electrons that reduce the ions of the plated metal to form the metal sheet or plated film. The deposition rate is proportional to the current. Thus, in order to accommodate and sustain a sufficient deposition rate, a high current must be supplied to the workpiece. The electric circuit in the system uses an anode, an electrolytic solution, and a cathode. The workpiece is typically the cathode and as current flows from the anode to the cathode, electrons are transferred from the cathode to the ions in the electrolyte to reduce those ions and deposit the film on the cathode. Depending on process conditions and the metal to be deposited, the current levels can vary, but during bulk deposition are typically between 10 and 40 A.

Electrical contact to the workpiece is achieved by means of a contact ring. Various designs for the contact ring exist in the art. There are four main categories of contact rings: wire (or open contact) contact ring, sealed contact ring, shielded contact ring, and embedded contact ring. In the case of unsealed contact rings, the electrical contacts between the workpiece and the ring are immersed in the electrolytic solution. In the case of the sealed ring, a seal separates the contacts from the solution. Thus, the electrical contacts in the unsealed rings (of all permutations) are “wet” whereas the electrical contacts of the sealed ring are “dry”.

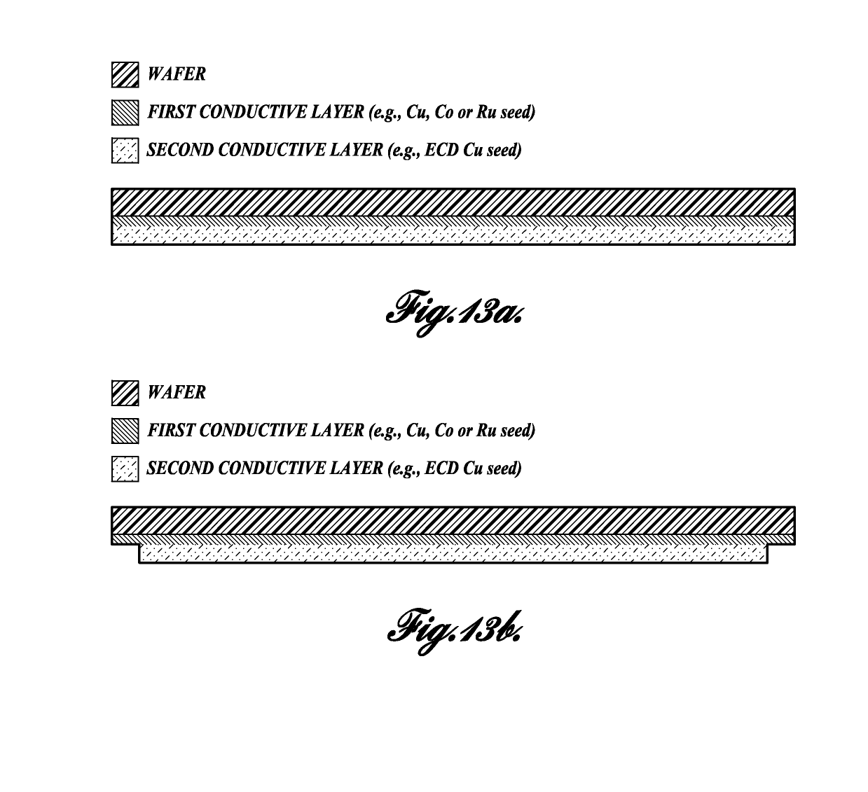

A clear distinction between sealed and unsealed contacts is that, in the case of sealed contacts, no material is plated or deposited in the area that is sealed because the sealed area is not exposed to the electrolyte during electrochemical deposition process. An exemplary workpiece deposition scheme for “dry” contacts is provided in FIG. 13B. In that regard, a first conducting layer or seed layer is deposited on a substrate, and a second conducting layer or ECD seed layer is deposited on the first conducting layer. As can be seen in FIG. 13B, there is a void in the second conducting layer at the location of the contacts.

In contrast, unsealed contacts result in deposition or plating on the entire surface of the workpiece that is exposed to the electrolyte, including the contact area. An exemplary workpiece deposition scheme for “wet” contacts is provided in FIG. 13A. In that regard, a first conducting layer or seed layer is deposited on a substrate, and a second conducting layer or ECD seed layer is deposited on the seed layer. Unlike the workpiece in FIG. 13B, there is no void in the second conducting layer at the location of the contacts on the workpiece in FIG. 13A.

As discussed above, thin seed layers or seed layers made from metals other than copper tend to have high sheet resistance. Also, as explained above, the current passed to the cathode must pass through the seed layer. There are at least four different contact configurations for ECD, as follows. First, the contacts may be from a sealed ring, for which all current must flow through the thin seed and no deposition takes place outside the perimeter of the sealed ring. Refer to U.S. Pat. No. 5,227,041, issued to Brogden et al., for an exemplary sealed contact ring configuration.

Second, the contacts may be made from an unsealed ring, for which deposition takes place on the entire surface of the workpiece. Refer to U.S. Patent Publication No. 2013/0134035, to Harris, for an exemplary unsealed contact ring configuration.

Third, in another embodiment, the unsealed contact ring may be have “shielded” contacts to provide additional control in the system, for example, to control the flow of chemistry and/or the generation of air bubbles in the system.

Fourth, the contacts may be made from a sealed ring with embedded contacts. Embedded contacts are generally positioned inside the seal ring so that the outer perimeter edge of the workpiece remains dry. The metal contacts may either protrude from or be flush with the seal so that their tips are in contact with the workpiece and the chemistry solution inside the perimeter of the sealed ring. In this third configuration, no electrochemical deposition takes place on the dry area outside the perimeter of the sealed ring; however, the tip of the contacts are exposed to the electrolyte and to the film being electrochemically deposited while reaction takes place.

High sheet resistance creates high heat conditions on the workpiece. First principle calculations and simulations show that power dissipation through a very thin seed layer of thickness varying between 1 nm and 10 nm and sheet resistance varying from about 1000 Ohm/square to less than 10 Ohm/square, could exceed 400 W. For example, a 1.5 nm thick film with resistivity of about 10 microOhms-cm and running at normal operating conditions of about 40 A would dissipate about 100 W. Accounting for the increase in resistivity associated with scattering of charge carriers and thin films properties, simulation shows that the heat dissipation of this film may exceed 400 W. Moreover, assuming that the contacts cover 50% of the workpiece circumference area, we calculate current density of about 20 MA/cm̂2. This current density value exceeds the ampacity of thin films which, according to the International Technology Roadmap for Semiconductors (ITRS), is between 2 and 3 MA/cm̂2, by a wide margin. Assuming adiabatic conditions we calculate that the heating rate of this film (dT/dt) would exceed 100 million K/s.

Although the film in question is not operating under adiabatic conditions, no known material can sustain such high heating rate and no known material can dissipate the heat generated at a sufficient rate to prevent rapid local heating. In experiments, the inventors found localized heating to be so great, that the dry part of a 5 nm Co film is capable of being damaged during electrochemical deposition, such as readily oxidizing or rapidly degrading. The thin film can oxidize under such heat, causing an open circuit and a stop to the electrochemical process. Therefore, it is difficult to deposit metal on a workpiece having a conductive layer having high sheet resistance using dry contacts, particularly with the current or current density is high, for example, exceeding 3 MA/cm2. High sheet resistance may be greater than 10, 50, or 100 ohm/square.

Embodiments of the present disclosure are directed to preventing such overheating. In cases in which the contacts are exposed to the electrolyte, the electrochemically deposited film creates a continuous film connecting the pins with the film deposited on the workpiece. For example, in the cases of an unsealed ring and an embedded sealed ring, electrochemical deposition of a film occurs at, near, and around the point of contact. As the electrochemically deposited film thickens during the electrochemical deposition process, the sheet resistance of the film rapidly decreases and the power dissipation quickly drops to near zero. Moreover, the liquid at the point of contact provides additional cooling and shielding from atmospheric oxygen, effectively preventing oxidation of the seed layer. Because heat dissipation quickly decreases, no significant heating of the seed layer takes place.

Moreover, the current profile can be adjusted to allow low current deposition at the initiation steps and higher current as the resistance drops. Because the heat dissipation is proportional to Î2, low initial current is an effective way to avoid seed damage. Current in such a current profile can vary in the range of about less than 1 A to about 80 A on a 450 mm wafer.

In accordance with embodiments of the present disclosure, high sheet resistance is in the range of greater than 10 ohm/sq., greater than 50 ohm/sq., greater than 100 ohm/sq., etc.

In accordance with one embodiment of the present disclosure an ECD seed layer is deposited on a seed layer having high sheet resistance.

In accordance with another embodiment of the present disclosure an ECD layer (for example, an ECD fill or ECD cap) is deposited on a seed layer having high sheet resistance.

In accordance with another embodiment of the present disclosure an ECD layer (for example, an ECD seed, ECD fill, or ECD cap) is deposited on an ECD seed layer having high sheet resistance.

In accordance with embodiments of the present disclosure, the ECD seed layer that is to be deposited upon may be a conformal layer or may first be subjected to an annealing process to at least partially fill the feature in accordance with other embodiments of the present disclosure.

While illustrative embodiments have been illustrated and described, it will be appreciated that various changes can be made therein without departing from the spirit and scope of the disclosure.

1. A method for at least partially filling a feature on a workpiece, the method comprising:
(a) obtaining a workpiece including a feature;
(b) depositing a first conductive layer in the feature, wherein the sheet resistance of the first conductive layer is greater than 10 ohm/square; and
(c) depositing a second conductive layer in the feature by electrochemical deposition, wherein the electrical contacts are at least partially immersed in the deposition chemistry.

2. The method of claim 1, wherein the first conductive layer is a seed layer.

3. The method of claim 2, wherein the seed layer is selected from the group consisting of seed, secondary seed, and a stack film of seed and liner.

4. The method of claim 2, wherein metal for each component of the seed layer is selected from the group consisting of copper, cobalt, nickel, gold, silver, manganese, tin, aluminum, ruthenium, and alloys thereof.

5. The method of claim 1, wherein the first conductive layer is deposited by a process selected from the group consisting of physical vapor deposition, chemical vapor deposition, atomic layer deposition, and electroless deposition.

6. The method of claim 1, wherein the second conductive layer is a cap or fill layer deposited by electrochemical deposition.

7. The method of claim 6, wherein the second conductive layer is deposited using an acid chemistry.

8. The method of claim 1, wherein the second conductive layer is a conformal conductive layer deposited by electrochemical deposition.

9. The method of claim 8, wherein the second conductive layer is deposited using an alkaline chemistry.

10. The method of claim 8, wherein the second conductive layer has a sheet resistance selected from the group consisting of greater than about 10 ohm/square, greater than about 50 ohm/square, greater than about 100 ohm/square.

11. The method of claim 8, further comprising heat treating the workpiece to reflow the second conductive layer to at least partially fill the feature.

12. The method of claim 11, further comprising depositing a cap, fill layer, or another conformal conductive layer on the reflowed second conductive layer.

13. The method of claim 1, further comprising depositing a barrier layer in the feature before the first conductive layer is deposited.

14. The method of claim 13, wherein the first conductive layer is deposited directly on the barrier layer.

15. The method of claim 1, wherein the sheet resistance of the first conductive layer is greater than 50 ohm/square or greater than 100 ohm/square.

16. The method of claim 10, wherein the sheet resistance of the second conductive layer is greater than 50 ohm/square or greater than 100 ohm/square.

17. The method of claim 1, wherein the critical dimension of the feature is selected from the group consisting of less than 30 nm, about 5 to less than 30 nm, about 10 to less than 30 nm, about 15 to about 20 nm, and about 20 to less than 30 nm, less than 20 nm, less than 100 nm, and about 5 to about 10 nm.

18. The method of claim 1, wherein the second conductive layer is deposited over the entire surface of the first conductive layer.

19. The method of claim 1, wherein the electrical contacts are selected from the group consisting of open contacts, unsealed contacts, embedded contacts, and shielded contacts.

20. A method for at least partially filling a feature on a workpiece, the method comprising:
(a) obtaining a workpiece including a feature;
(b) depositing a seed layer in the feature, wherein the sheet resistance of the first conductive layer is greater than 10 ohm/square; and
(c) depositing a conductive layer in the feature on the seed layer by electrochemical deposition, wherein the electrical contacts are at least partially immersed in the deposition chemistry.

21. A workpiece, comprising:
(a) a feature;
(b) a first conductive layer in the feature, wherein the sheet resistance of the first conductive layer is greater than 10 ohm/square; and
(c) a second conductive layer in the feature, wherein the second conductive layer covers the entire surface of the first conductive layer.
